(19) United States
(12) Patent Application Publication
(10) Pub. No.: US 2007/0120178 A1
(43) Pub. Date: May 31, 2007

(54) Electrochemical cell structure and method of fabrication

(75) Inventors: Barry McGregor, Cambridgeshire (GB); Masaya Ishida, Cambridgeshire (GB)

Correspondence Address: OLIFF & BERRIDGE, PLC, P.O. BOX 19928, ALEXANDRIA, VA, 22320, US

(73) Assignee: SEIKO EPSON CORPORATION, TOKYO (JP)

(21) Appl. No.: 11/598,799

(22) Filed: Nov. 14, 2006

(30) Foreign Application Priority Data
Nov. 25, 2005 (GB) 0524073.4

(51) Int. Cl. H01L 29/788

(52) U.S. Cl. 257/321

(57) ABSTRACT

A method of forming a metal oxide layer for an electrochemical cell is provided. The method includes: forming a plurality of adjacent metal oxide cells, spaced from one another; and performing localised heating of the plurality of adjacent metal oxide cells. A method of forming an electrochemical cell is also provided. The method includes: forming a first conductive oxide layer; forming the metal oxide layer on the first conductive layer; forming a functional dye layer on the metal oxide layer; and forming a second conductive layer; and providing an electrolyte between the functional dye layer and the second conductive layer, wherein at least one of the first and second conductive layers is transparent.

### FIELD OF THE INVENTION

The present invention relates to an electrochemical cell structure and a method of fabrication.

### BACKGROUND OF THE INVENTION

The International Energy Agency's “World Energy Outlook” predicts that global primary energy demand will increase by 1.7% per year from 2000 to 2030. It also predicts that 90% of this demand will be met by fossil fuels. Consequently, there will be a 1.8% per year increase in carbon dioxide from 2000 to 2030, reaching 38 billion tonnes in 2030. Cleaner, renewable energy sources, including solar cells, have long been heralded as counters to this increased pollution trend. While advanced silicon based solar cells are now widely commercially available, their uptake has been slow due to high production costs, a lack of robustness and associated visual pollution resulting from the large surface exposure requirements.

Dye Sensitised Solar Cells (DSSC) are an alternative to crystalline solar cells that are cheaper than crystalline solar cells to produce. However, DSSC's are less efficient than crystalline solar cells. Therefore, DSSC's require significant area coverage to be effective power generators.

U.S. Pat. No. 4,927,721 entitled “Photo-Electrochemical Cell”, by M Gratzel et al. discloses a typical DSSC. As illustrated in FIG. 1, the DSSC 10 comprises a first transparent insulating layer 1; a first transparent conductive oxide (TCO) electrode layer 2; a transparent metal oxide layer 3 of titanium dioxide (TiO₂); a molecular monolayer of sensitiser (dye) 4; an electrolyte layer 5; a second transparent conductive oxide (TCO) electrode layer 6; and a second transparent insulating layer 7.

A DSSC generates charge by the direct absorption of visible light. Since most metal oxides absorb light predominantly in the ultra-violet region of the electromagnetic spectrum, a sensitiser (dye) 4 is absorbed onto the surface of metal oxide layer 3 to extend the light absorption range of the solar cell into the visible light region.

In order to increase the amount of light that the metal oxide layer 3 and the sensitiser (dye) layer 4 can absorb, at least some portion of the metal oxide layer 3 is made porous, increasing the surface area of the metal oxide layer 3. This increased surface area can support an increased quantity of sensitiser (dye) 4 resulting in increased light absorption and improving the energy conversion efficiency of the DSSC to more than 10%.

An electrochromic display (ECD) is a relatively new electrochemical, bi-stable display. While the application is different to the DSSC, these devices share many physical attributes, illustrated in FIG. 1, exchanging the sensitiser (dye) layer 4 by an electrochromic material layer which undergoes a reversible colour change when an electric current or voltage is applied across the device; being transparent in the oxidised state and coloured in the reduced state.

When a sufficient negative potential is applied to the first transparent conductive oxide (TCO) electrode layer 2, whilst the second transparent conductive electrode oxide (TCO) layer 6 is held at ground potential, electrons are injected into the conduction band of the metal oxide semiconductor layer 3 and reduce the adsorbed molecules (the coloration process). The reverse process occurs when a positive potential is applied to the first transparent conductive oxide (TCO) electrode layer 2 and the molecules become bleached (transparent).

A single electrochromic molecular monolayer on a planar substrate would not absorb sufficient light to provide a strong colour contrast between the bleached and unbleached states. Therefore a highly porous, large surface area, nanocrystalline metal oxide layer 3 is used to promote light absorption in the unbleached state by providing a larger effective surface area for the electrochromophore to bind onto. As light passes through the thick metal oxide layer 3, it crosses several hundreds of monolayers of molecules coloured by the sensitiser (dye) 4, giving strong absorption.

Since the structure of both electrochemical devices is similar, we describe only the method of DSSC manufacture as an example. Equally, this process could be applied with little modification to the ECD manufacture.

In order to manufacture the DSSC 10 illustrated in FIG. 1, a metal oxide layer 3 of several microns thickness is deposited onto the first transparent conductive oxide (TCO) electrode layer 2, using any one of several techniques, such as screen printing, doctor blading, sputtering or spray coating a high viscosity paste. A typical paste consists of water or organic solvent based metal oxide nanoparticle suspensions (5-500 nm diameter), typically titanium dioxide (TiO₂), a viscosity modifying binder, such as polyethylene glycol (PEG), and a surfactant, such as Triton-X. Following deposition the paste is dried to remove the solvent, and then sintered at temperatures up to 450° C. This high temperature process modifies the metal oxide particle size and density, and ensures the removal of the organic binder constituents, such as polyethylene glycol (PEG) to provide a good conductive path throughout and a well defined material porosity. Sintering also provides good electrical contact between the metal oxide particles 3 and the first transparent conductive oxide (TCO) electrode layer 2.

After drying and cooling, the porous metal oxide layer 3 is coated with sensitiser (dye) 4 by immersion in a low concentration (≦1 nM) sensitiser (dye) solution for an extended period, typically 24 hours, to allow absorption of the sensitiser (dye) 4 onto the metal oxide layer 3 through a functional ligand structure that often comprises a carboxylic acid derivative. Typical solvents used in this process are acetonitrile or ethanol, since aqueous solutions would inhibit the absorption of the sensitiser (dye) 4 onto the surface of the metal oxide layer 3.

The first transparent conductive oxide (TCO) electrode layer 2, having the porous metal oxide layer 3 and sensitiser (dye) layer 4 formed thereon, is then assembled with the second transparent conductive oxide (TCO) electrode layer 6. Both electrode layers 2, 6 are sandwiched together with a perimeter spacer dielectric encapsulant to create an electrode-to-electrode gap of at least 10 μm, before filling with the electrolyte layer 5. The spacer material is most commonly a thermoplastic that provides an encapsulation seal. Once the electrolyte layer 5, which is most commonly an iodide/triiodide salt in organic solvent, is introduced, the DSSC is completed by sealing any remaining aperture with either a thermoplastic gasket, epoxy or a UV-curable resin to prevent the ingress of water and hence device degradation.

Most, if not all, of the materials used to fabricate the DSSC can be handled in air and also under atmospheric pressure conditions, removing the necessity for expensive vacuum processes associated with crystalline solar cell fabrication. As a result, a DSSC can be manufactured at a lower cost than a crystalline solar cell.

The ECD fabrication process is very similar to that for the DSSC, with several exceptions. The porous metal oxide layer 3 is often patterned by screen printing to provide a desired electrode image, allowing the device to convey information by colouring or bleaching selected regions. Additionally, the sensitiser (dye) layer 4 is replaced with an absorbed electrochromophore material layer. Furthermore, a permeable diffuse reflector layer, typically large particles of sintered metal oxide, can be positioned between the first and second electrode layers 2, 6 to increase the viewed image contrast.

U.S. Pat. No. 5,830,597, entitled “Method and Equipment for Producing a Photochemical Cell”, by H Hoffmann also discloses a DSSC 100. As illustrated in FIG. 2, the DSSC 100 comprises a first substrate 101 of glass or plastic; a first transparent conductive oxide (TCO) layer 102; a titanium dioxide (TiO₂) layer 103, a dye layer 104; an electrolyte layer 105; a second transparent conductive oxide (TCO) layer 106; a second substrate 107 of glass or plastic; and insulating webs 108, 109. The insulating webs 108, 109 are used to form individual cells 110 in the DSSC 100.

An individual cell 110 formed between the insulating web 108 and the insulating web 109 is different from the adjoining individual cell 110 formed between the insulating web 109 and the insulating web 108. This is because the TiO₂ layer 103 and the electrolyte layer 105 are interchanged in each adjoining individual cell 110. Thus, the electrical polarity of the adjoining individual cells 110 is opposite. This alternate division of different layers results in the formation of conducting layers 111 from the electrically conductive layers 102 and 106, each conducting layer 111 connecting a positive (negative) pole of one individual cell 110 to the negative (positive) pole of an adjacent individual cell 110. The resultant structure provides a method of increasing the overall DSSC output voltage, without the necessity of incorporating a multi-layered structure.

“Preparation of TiO₂ Nanocrystalline Electrode for Dye-Sensitised Solar Cells by 28 GHz Microwave Irradiation”, by S Uchida et al., Solar Energy Materials & Solar Cells 81 (2004), pages 135 to 139 discloses the rapid synthesis of TiO₂ nanocrystals on a transparent conductive oxide glass electrode for use in dye-sensitised solar cells by using 28 GHz microwave irradiation.

In order to improve the incident photon to current conversion efficiency and control the stability/reproducibility of the DSSC performance, it is important to precisely control the physical properties of the metal oxide layer, and hence the absorption of the sensitiser (dye) molecule. However, metal oxide layer fabrication using screen-printing often results in a ±5% film thickness variation caused by residual blocked or dirty screen cells, adhesion to the screen during separation from the substrate surface and trapped bubble expansion during drying, caused by the inability to completely outgas a viscous paste. Other methods, such as doctor-blading, also suffer from an inability to provide a well defined thick metal oxide layer without significant spatial deviations. Subsequent porosity and film quality deviations are therefore likely to occur throughout such metal oxide layers, resulting in a degradation of efficiency and image quality for the DSSC and ECD, respectively.

In the case of the ECD, screen-printing demands are further exacerbated by the requirement to create ever finer metal oxide layer features for higher quality images, i.e. increase the dots-per-inch (dpi) for a pixelated display. As the dpi increases, the smallest feature size becomes limited as the screen mesh size approaches the mesh partition width.

As a result, fabrication of an electrochemical device based on a functionally sensitised thick porous metal oxide layer, as for the DSSC and ECD, using the aforementioned fabrication techniques are inappropriate from the view points of device reproducibility and adaptability to large size device production.

### SUMMARY OF THE INVENTION

The present invention aims to address the above mentioned problems of manufacturing electrochemical cells (DSSC's and ECD's) of the prior art, to improve the efficiency with which they are made and thus further decrease their costs.

In a first embodiment of the present invention a method of forming a metal oxide layer for an electrochemical cell is provided. The method comprising: forming a plurality of adjacent metal oxide cells, spaced from one another; and performing localised heating of the plurality of adjacent metal oxide cells.

In one embodiment microwave irradiation is used to perform the localised heating. In another embodiment 28 GHz of microwave irradiation is applied. In another embodiment laser irradiation is used to perform the localised heating. In another embodiment the laser has a wavelength of substantially 360 nm.

In a first embodiment of the present invention a method of forming an electrochemical cell is provided. The method comprising: forming a first conductive layer; forming the metal oxide layer according to any preceding claim on the first conductive layer; forming a functional dye layer on the metal oxide layer; forming a second conductive layer; and providing an electrolyte between the functional dye layer and the second conductive layer, wherein at least one of the first and second conductive layers is transparent.

In one embodiment the method further comprises: forming separating means on the first surface of the first transparent conductive layer surrounding each of the plurality of adjacent metal oxide cells. In another embodiment the metal oxide layer is inkjet printed onto the first conductive layer prior to localised heating. In another embodiment the metal oxide layer is inkjet printed onto the first conductive oxide layer in one step prior to localised heating.

In another embodiment the method further comprises: providing an electrocatalytic layer between the electrolyte and the second conductive layer. In another embodiment the method further comprises: providing a reflector layer on the opposite side of the functional dye layer to the at least one transparent conductive layer. In another embodiment the method further comprises: forming the first conductive layer on a first insulating substrate, whereby the first insulating substrate and the metal oxide layer are on opposite sides of the first conductive layer. In another embodiment the method further comprises: forming the second conductive layer on a second insulating substrate, whereby the second insulating substrate and the electrolyte are on opposite sides of the second conductive layer.

The method of fabrication of the electrochemical cell of the present invention, using inkjet printing, is advantageous over screen printing fabrication as format scaling (up or down) does not require re-investment in machine hardware. This is because inkjet fabrication is software controlled and the software can be reconfigured without the expense of commissioning new screens. Additionally, inkjet heads are significantly more durable, than patterned screens, as patterned screens last only approximately 100 uses.

Furthermore, the drop on demand placement enabled by inkjet fabrication is less wasteful than screen printing. Unlike conventional inkjet overwriting, where each deposited layer is dried and then printed over to produce a thick deposition, the inkjet flood filling technique, which doses a confined region with a large volume of liquid to provide the required deposit thickness, has been shown to produce fracture-free metal oxide layers. Moreover, the surface confinement used to enable flood filling, through the use of a bank structure, ensures long range uniform material distribution and therefore uniform and repeatable performance.

### BRIEF DESCRIPTION OF THE DRAWINGS

Embodiments of the present invention will now be described by way of further example only and with reference to the accompanying drawings, in which:

FIG. 1 illustrates a typical Dye Sensitised Solar Cell (DSSC) of the prior art;

FIG. 2 illustrates a further DSSC of the prior art;

FIG. 3 illustrates an electrochemical cell of the present invention; and

FIG. 4 illustrates a process flow diagram for the fabrication of an electrochemical cell of the present invention.

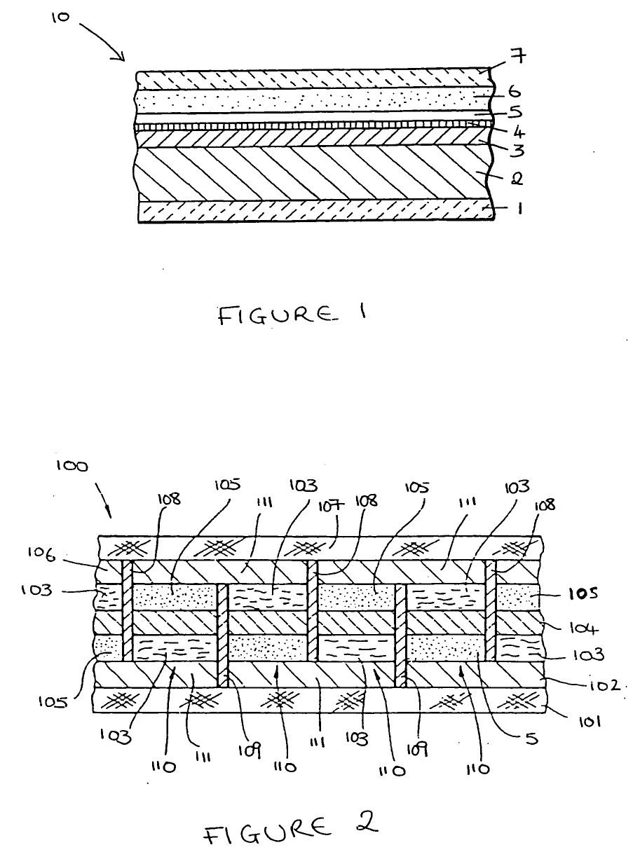

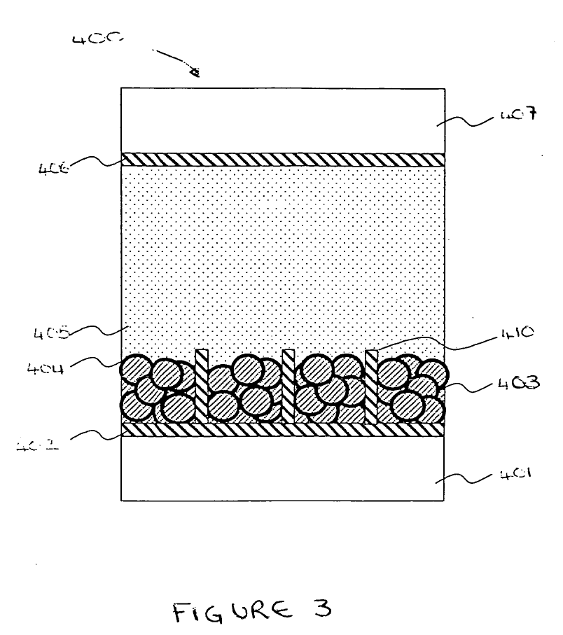

### DETAILED DESCRIPTION

The present invention relates to an electrochemical cell such as a Dye Sensitised Solar Cell (DSSC) or an electrochromic display (ECD). One electrochemical cell 400 of the present invention comprises, with reference to FIG. 3, a first transparent insulating substrate layer 401; a first transparent conductive oxide (TCO) electrode layer 402; a metal oxide layer 403; a sensitiser (dye)/electrochromic material layer 404; an electrolyte layer 405; a second TCO electrode layer 406; and a second transparent insulating substrate layer 407.

The first and second transparent insulating substrate layers 401, 407 are preferably glass or plastic. The metal oxide layer 403 is preferably titanium dioxide (TiO₂) and is a semiconductor.

The metal oxide layer 403 should preferably be a material which promotes intimate adhesion of the sensitiser (dye)/electrochromic material layer 404 on its surface. Additionally, the particles of the metal oxide layer 403 must be reasonably light transmissible. Particles greater then 500 nm are expected to be opaque and are not generally considered appropriate for use in the present invention. Such large particles would also tend to cause inkjet nozzle blocking.

In a first embodiment of the present invention, a bank structure 410 is formed on the first TCO layer 402, prior to the application of the metal oxide layer 403, so that a metal oxide layer 403 is formed of isolated cells. In one embodiment the bank structure 410 may be formed from a polymer or a polyimide.

Preferably, the bank structure is hydro- and/or oleophobic in some part while the TCO layer 402 is hydro- and/or oleophilic, depending on the nature of the metal oxide ink used to form the metal oxide layer 403.

The bank structure 410 can take on any desired shape forming a matrix of individual pixel cells on the first TCO layer 402, within which the isolated metal oxide cells are formed; such that no metal oxide bridges the bank structure 410 to cause short circuiting.

When the electrochemical cell is an ECD, it is essential that all the metal oxide cells (pixels) are electrically isolated from one another to control the image formation. While the metal oxide cell electrical isolation is not essential when the electrochemical cell is a DSSC, it is preferable to maintain a uniform metal oxide distribution throughout the active device area.

The ECD electrochemical cell can be considered as being composed of a plurality of micro-electrochemical cells, and different micro-electrochemical cells may have different coloured electrochromophore layers 404. Each micro-electrochemical cell is separated from the other micro-electrochemical cells, which together form the ECD, by the bank structure 410. Each micro-electrochemical cell is preferably between 20 μm to 500 μm across.

In a further embodiment of the present invention an electrocatalytic layer can be formed between the electrolyte layer 405 and the second TCO layer 406. The electrocatalytic layer is preferably greater than 2 nm thick and is selected to enhance the electrolyte regeneration. In the case of the DSSC, effective electrocatalytic metals can be selected from the platinum group metals; platinum, ruthenium, rhodium, palladium, iridium or osmium. The use of an electrocatalytic layer improves the overall performance of the electrochemical cell of the present invention.

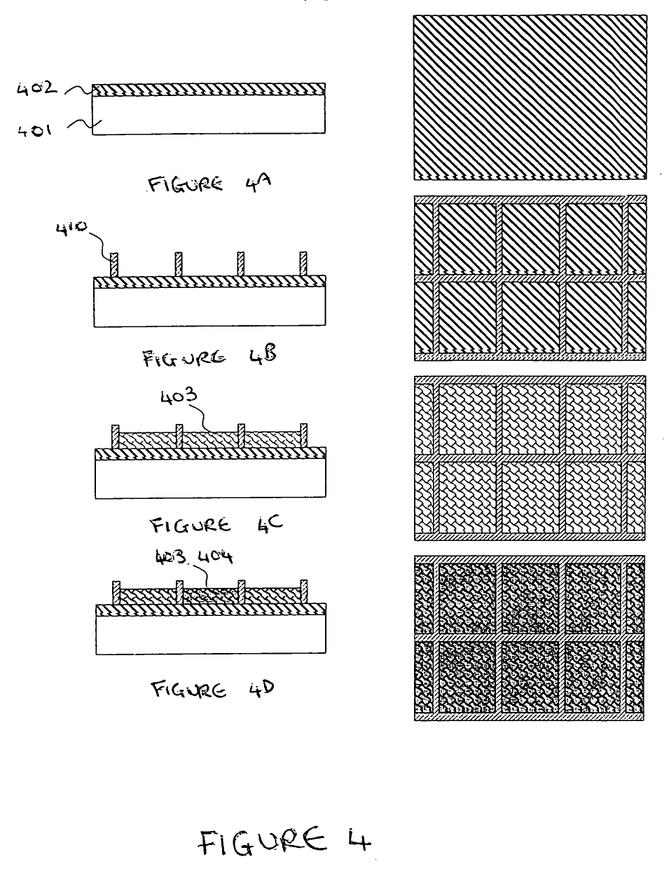

The present invention also relates to a method of fabricating the electrochemical cell 400 of the present invention. FIG. 4 illustrates a process flow diagram for the fabrication of an electrochemical cell 400 of the present invention.

The TCO layer 402 is formed on the first transparent insulating substrate layer 401, FIG. 4a. Preferably, the TCO layer 402 has a sheet resistivity of 8-10 Ω·sq and is made of indium tin oxide or fluorine doped tin oxide.

The bank structure 410 is then fabricated on the TCO layer 402, FIG. 4b. In the first embodiment of the present invention, the bank structure 410 forms a matrix of square pixel cells. In order to form the bank structure 410 on the TCO layer 402, a photo-reactive acrylic polymer source material is coated on to the TCO layer 402 and dried. A mask, in the shape of the matrix of pixel cells is then applied to the TCO layer 402. An ultraviolet (UV) light is irradiated through the mask to cause cross-linking of the acrylic polymer in the exposed regions. The unexposed regions are removed by chemical developing, and the bank structure 410 is thermally cured at 130° C.

The TCO layer 402 having a bank structure 410 is then treated by oxygen or oxygen plus carbon tetrafluoride plasma to remove residual polyimide in the exposed regions. A carbon tetrafluoride (CF₄) plasma treatment is then applied to cause the polyimide bank structure 410 to become hydrophobic, while preserving the hydrophilic surface of the TCO layer 402.

The metal oxide layer 403 is then inkjet printed onto the TCO layer 402 having the bank structure 410 formed thereon. The metal oxide ink is jetted into each of the isolated pixel cells to form the metal oxide layer 403, FIG. 4c. Preferably, aqueous colloidal titanium dioxide (TiO₂) inks of concentration ≦10% volume fraction (v/v) are used, containing particles <500 nm in diameter. Other additives can be included in the metal oxide ink to ensure compatibility of the solution with the inkjet head.

Each pixel cell of the metal oxide layer 403 is then subjected to localised heating in order to dry and then sinter the metal oxide, however, the substrate is not heated during the localised heating. Laser or microwave irradiation at a wavelength which can be absorbed by the metal oxide can be used to perform this localised heating.

When microwave irradiation is used to perform the localised heating, 28 GHz of microwave irradiation for a period of 5 minutes at 1.0 kW power output is preferred. When laser irradiation is used to perform the localised heating, a wavelength of 364 nm (Argon laser) and power of 1 W is preferable. The period of irradiation is preferably less than 1 minute at a laser beam radius of 500 μm. The metal oxide layer is irradiated by laser or microwave from the opposite side to the substrate.

When compared with a conventional drying and sintering step, the use of localised heating reduces the processing time, and removes the need for a closed oven. Additionally, the use of localised heating reduces the production line length by approximately one third and enables a continuous production process to result.

As the substrate is not heated during the localised heating of the metal oxide layer 403 a plastic substrate can be used, enhancing the flexibility of the electrochemical cell.

The thickness of the metal oxide layer 403 is controlled by the concentration of the aqueous colloidal TiO₂ ink, and the deposition volume. The resultant deviation in the peak thickness of the metal oxide layer 403 is less than 1.5% between pixel cells over a 50 cm² substrate area.

The substrate layer 401 comprising the TCO layer 402, the bank structure 410 and the metal oxide layer 403 is then immersed in sensitiser (dye) 404 for a period of time. The sensitiser (dye) 404 is thereby absorbed onto the surface of the metal oxide layer 403, FIG. 4d. For the DSSC example, the substrate was immersed in a 0.3 mM solution of N719 (obtained from Solaronix) in dry ethanol for 24 hours. After immobilisation of the sensitiser (dye) 404, the substrate is rinsed in ethanol and blown dry using nitrogen.

The first TCO layer 402, having the porous metal oxide layer 403 and sensitiser (dye) layer 404 formed thereon, is then assembled with the second TCO layer 406. Both electrode layers 402, 406 are sandwiched together with a perimeter spacer to create an electrode-to-electrode gap, before filling with the electrolyte layer 405. Once the electrolyte layer 405 is introduced, the DSSC is completed by sealing the remaining aperture.

If an electrocatalytic layer is desired in the electrochemical cell of the present invention, then the electrocatalytic layer is formed on the second TCO layer 406 prior to the electrode layers 402, 406 being sandwiched together.

An inkjet head is capable of providing a well defined aqueous colloidal metal oxide ink droplet, with volume deviation less than ±1.5%, to a precise location on the TCO layer 402. Moreover, this volumetric accuracy of ≦1.5% represents that for a commercial printer head. Several industrial heads and complementary techniques are available which can reduce this figure to ≦1%.

Inkjet deposition enables accurate positioning of the metal oxide on the TCO layer 402, within each pixel cell of the bank structure 410 as required. Thus, the thickness of the metal oxide layer 403 can be controlled precisely and a uniform porous metal oxide layer 403 can be obtained.

When at least part of the bank structure 410 is hydro- and/or oleophobic, and at least part of the TCO layer 402 is hydro- and/or oleophilic, the bank structure 410 repels the deposited metal oxide ink, thus correcting the final position of the deposited metal oxide ink droplets on the target surface and compensating for the inherent ±15 μm droplet lateral divergence from the inkjet nozzle axis. This repulsion is especially beneficial in the case of the ECD to prevent pixel short-circuits caused by metal oxide 403 bridging the bank structure 410. The bank structure 410 also enables the formation of a narrower gap between ECD pixels than otherwise permitted by the 30 μm spacing necessary for bank-less free-printing, enabling a higher active area ratio to be obtained in the ECD and increased image quality.

The metal oxide layer 403 should be several microns thick to function effectively. In traditional inkjet printing the thickness of the deposit is built up to the desired profile by using an overwriting technique, wherein each deposited layer is dried and sintered and then overwritten with another layer of ink, and so on, until the desired thickness is reached.

However, the method of the present invention uses a flood filling technique, whereby a large volume of metal oxide ink is introduced into each pixel cell of the bank structure 410 in one pass. The bank structure 410 prevents the metal oxide ink from spreading into neighbouring pixel cells. Using this process, only a single drying and sintering stage is required to produce the desired thickness of the metal oxide layer 403.

A bank structure 410 having a matrix of square pixel cells produces a quasi-pyramidal dry metal oxide topography when the flood filling technique is used to fill each pixel cell with metal oxide ink. The bank structure 410 acts to confine the deposited metal oxide ink to a local region, within the pixel cells on the TCO layer 402. Without this confinement, the metal oxide ink would be distributed freely across the TCO layer 402 following deposition and would form a continuous metal oxide layer 403.

The bank structure 410 of the present invention increases the metal oxide layer's 403 ability to accommodate bending stress without fracturing, compared to a continuous metal oxide layer 403. This enables a flexible substrate 401 to be utilised, such as a plastic first insulating substrate 401.

In the first embodiment of the present invention, the bank structure 410 comprises a matrix of square pixel cells. However, the pixel cells are not limited to being square. When the electrochemical cell 400 of the present invention is an ECD, square pixels are preferred as they are compatible with active matrix backplane fabrication technology. However, when the electrochemical cell 400 of the present invention is a DSSC, several different pixel cell shapes can be used, such as triangular, rectangular, circular or hexagonal.

DSSC's which are fabricated by sintering the metal oxide layer at 300° C., have an energy conversion efficiency (η), an open circuit voltage (V_{oc}), a short circuit current (I_{sc}) and a fill factor (FF) of 5.0%, 0.48 V, 15 mA/cm² and 56%, respectively.

DSSC's which are fabricated using microwave irradiation have been made with η, V_{oc}, I_{sc} and FF of 4.8%, 0.46 V, 13 mA/cm² and 52%, respectively. In addition, DSSC's which are fabricated using laser irradiation have been made with η, V_{oc}, I_{sc} and FF of 4.6%, 0.47 V, 13 mA/cm² and 54%, respectively. Therefore, it can be seen that the use of localised heating for fabrication of the metal oxide layer of the present invention does not significantly alter the properties of the DSSC.

Wider bank structures 410 are deleterious to both ECD operation, by a reduction in image quality, and DSSC operation, by a reduction in efficiency; resulting from a decrease in active area. Therefore, the bank structure 410 has a preferable width from 0.2 μm to 20 μm. 0.2 μm is the resolution limit for cost effective fabrication of the bank structure 410 by photolithography. 20 μm is considered the maximum effective bank structure 410 width before serious degradation of the image and performance becomes inhibitive, compared to the lowest common display resolutions of 72 dpi. Using inkjet technology hydrophilic pixel cell sizes less than 1 mm² are readily achievable, though lengths less than several hundred microns are preferred.

In the case of DSSC, absorption of light is proportional to the thickness of the porous metal oxide layer 403. If too thin, a fraction of the incident light will pass unhindered through the metal oxide layer 403, with a loss of potential efficiency. If too thick, once all of the useful light has been completely absorbed, any remaining metal oxide layer 403 thickness will be redundant. Therefore, preferably the thickness of the deposited metal oxide layer 403 should be between from 0.5 μm to 20 μm.

Moreover, due to the uniformity of the thickness of the metal oxide layer 403 produced by inkjet printing over screen printing, the optimal metal oxide layer 403 thickness can be thinner when using inkjet printing.

Furthermore, in the case of screen printing, the ink viscosity must be much higher than that preferred for inkjet printing. Therefore, the material added to increase viscosity must be removed during the sintering process. Consequently, the as-deposited, pre-sintered metal oxide layer 403 thickness must be greater for screen-printing than for inkjet printing.

Although a bank structure 410 is used to form a matrix of isolated pixel cells on the TCO layer 402, prior to application of the metal oxide ink, the present invention is not limited to banks. Any method of forming isolated pixel cells on the TCO layer 402 may be used, such by creating troughs in the TCO layer 402 or surface energy patterns on the TCO layer. These and other alternative methods may avoid the use of thermal curing steps and thereby increase the number of materials that can be used as a substrate.

Additionally, although the sensitiser (dye) 4 is formed on the metal oxide layer 403 by immersion of the metal oxide layer 403 in the sensitiser (dye) 404 for a predetermined period of time, the sensitiser (dye) 404 may be formed on the metal oxide layer using different techniques. For example, the sensitiser (dye) 404 may be ink jet printed onto the metal oxide layer 403 following formation of the metal oxide layer 403.

Furthermore, it is not essential for the first transparent conductive oxide layer 402 to be formed of an oxide material for the electrochemical cell of the present invention to function. Additionally, it is not essential for the second transparent conductive oxide layer 406 to be transparent or formed of an oxide material for the electrochemical cell of the present invention to function. Indeed, it is not essential to provide the second substrate (or either substrate in the finished device).

Any suitable material can be used for the bank structures. However, it is preferred to deposit them as a polymer, and more preferably as an acrylic polymer or a polyimide, pattern.

The foregoing description has been given by way of example only and it will be appreciated by a person skilled in the art that modifications can be made without departing from the scope of the present invention.

1. A method of forming a metal oxide layer for an electrochemical cell comprising:
forming a plurality of adjacent metal oxide cells, spaced from one another; and
performing localised heating of the plurality of adjacent metal oxide cells.

2. The method of forming a metal oxide layer for an electrochemical cell according to claim 1, wherein microwave irradiation is used to perform the localised heating.

3. The method of forming a metal oxide layer for an electrochemical cell according to claim 2, wherein 28 GHz of microwave irradiation is applied.

4. The method of forming a metal oxide layer for an electrochemical cell according to claim 1, wherein laser irradiation is used to perform the localised heating.

5. The method of forming a metal oxide layer for an electrochemical cell according to claim 4, wherein, the laser has a wavelength of substantially 360 nm.

6. A method of forming an electrochemical cell, comprising:
forming a first conductive layer;
forming the metal oxide layer according to claim 1 on the first conductive layer;
forming a functional dye layer on the metal oxide layer;
forming a second conductive layer; and
providing an electrolyte between the functional dye layer and the second conductive layer,
wherein at least one of the first and second conductive layers is transparent.

7. The method of forming an electrochemical cell according to claim 6, further comprising:
forming separating means on the first surface of the first transparent conductive layer surrounding each of the plurality of adjacent metal oxide cells.

8. The method of forming an electrochemical cell according to claim 6, wherein the metal oxide layer is inkjet printed onto the first conductive layer prior to localised heating.

9. The method of forming an electrochemical cell according to claim 8, wherein the metal oxide layer is inkjet printed onto the first conductive oxide layer in one step prior to localised heating.

10. The method of forming an electrochemical cell according to claim 6, further comprising:
providing an electrocatalytic layer between the electrolyte and the second conductive layer.

11. The method of forming an electrochemical cell according to claim 6, further comprising:
providing a reflector layer on the opposite side of the functional dye layer to the at least one transparent conductive layer.

12. The method of forming an electrochemical cell according to claim 6, further comprising:
forming the first conductive layer on a first insulating substrate, whereby the first insulating substrate and the metal oxide layer are on opposite sides of the first conductive layer.

13. The method of forming an electrochemical cell according to claim 12, further comprising:
forming the second conductive layer on a second insulating substrate, whereby the second insulating substrate and the electrolyte are on opposite sides of the second conductive layer.

14. A method of forming an electrochemical cell comprising the method according to claim 1.
